(19) United States
(12) Patent Application Publication
(10) Pub. No.: US 2013/0093532 A1
(43) Pub. Date: Apr. 18, 2013

(54) FLEXIBLE PRINTED CIRCUIT BOARD

(71) Applicant: FUJIKURA LTD., Tokyo (JP)

(72) Inventors: Hirohito Watanabe, Sakura-shi (JP); Masakazu Sato, Sakura-shi (JP); Taiji Ogawa, Sakura-shi (JP)

(73) Assignee: FUJIKURA LTD., Tokyo (JP)

(21) Appl. No.: 13/647,596

(22) Filed: Oct. 9, 2012

(30) Foreign Application Priority Data
Oct. 17, 2011 (JP) 2011-228114

(51) Int. Cl. H01P 3/08; H05K 1/02

(52) U.S. Cl. 333/33; 174/254; 333/246

(57) ABSTRACT

A flexible printed circuit board including: a base substrate; a pad formed on one surface side of the base substrate; and a ground plane layer formed on the other surface side of the base substrate, the ground plane layer including a ground-removed portion, the ground-removed portion being formed at a position facing the pad via the base substrate so as to be of similar shape to the pad and have an outer shape extended 100±50 μm outwardly from an outer shape of the pad.

### CROSS-REFERENCE TO RELATED APPLICATIONS

This application is based upon and claims the benefit of priority from the prior Japanese Patent Application No. 2011-228114, filed on Oct. 17, 2011, the entire contents of which are incorporated herein by reference.

### BACKGROUND OF THE INVENTION

1. Field of the Invention

The present invention relates to a flexible printed circuit board having outstanding high frequency characteristics.

2. Description of the Related Art

Conventionally, a component mounting pad or connector pad for surface mounting an electronic component in a flexible printed circuit board for high-speed signal transmission is formed with a broader width than the signal transmission wiring. Moreover, a surface of the flexible printed circuit board on an opposite side to the pad is provided with a ground plane layer formed on its entire surface.

If a flexible printed circuit board having such a structure is used as it is, characteristic impedance of the pad portion changes and reflection occurs resulting in the signal being disturbed.

Accordingly, in a circuit board disclosed in Unexamined Japanese Patent Application Publication No. JP07-307578 A (Document 1) , a first ground/power supply plane layer is formed, via a first dielectric layer, below a first signal transmission conductor layer including a pad, a hollowed-out portion is formed in a portion of the first ground/power supply plane layer corresponding to the pad, and a second ground/power supply plane layer is further formed, via a second dielectric layer, below the hollowed-out portion.

This has the aim of expanding a distance from the pad to the ground at the pad portion to thus cause capacitance to lower and characteristic impedance of the pad portion to increase, and thereby prevent disturbance of the signal.

### SUMMARY OF THE INVENTION

However, in the circuit board disclosed in the above-mentioned Document 1, in order to generate distance between the pad and the ground, a substrate (circuit board) structure having at least four or more layers of conductor layers is required. There is thus a problem that when applying this structure to a thin, easily-bent flexible printed circuit board, it inevitably becomes necessary to trade off flexibility in order to maintain characteristic impedance.

There is also a problem that, considering the advance in increased functionality of printed wiring circuits, diversification in characteristics required of printed wiring circuits, and so on, in recent years, or the increased requirement to lower manufacturing costs of printed wiring circuits in recent years, and so on, it is difficult in reality to change a material to LCP or perform a structural change such as providing an air layer as in the above-mentioned Document 1, simply for the sake of electrical characteristics.

This invention has an object of solving the above-described problems arising from the conventional technology to thereby provide a flexible printed circuit board having outstanding high frequency characteristics and which can realize a stable characteristic impedance while having good flexibility.

A flexible printed circuit board according to one embodiment of the present invention includes: a base substrate; a pad formed on one surface side of the base substrate; and a ground plane layer formed on the other surface side of the base substrate, the ground plane layer including a ground-removed portion, the ground-removed portion being formed at a position facing the pad via the base substrate so as to be of similar shape to the pad and have an outer shape extended 100±50 outwardly from an outer shape of the pad.

The flexible printed circuit board according to one embodiment of the present invention results in a pad being formed in one surface of a base substrate and a ground plane layer being formed in the other surface of the base substrate, and in a ground-removed portion being formed at a position in the ground plane layer facing the pad via the base substrate, the ground-removed portion being of similar shape to the pad and having an outer shape extended 100±50 μm outwardly from an outer shape of the pad. That is, the flexible printed circuit board according to one embodiment of the present invention is configured by a substrate structure of two layers of conductor layers. Moreover, lines of electric force are concentrated between sides of the pad and sides of the ground-removed portion, and these are in balance with inductance of the pad. As a result, the flexible printed circuit board according to one embodiment of the present invention has outstanding high frequency characteristics and realizes a stable characteristic impedance while having good flexibility.

In one embodiment of the present invention, a difference in outer shape between the pad and the ground-removed portion is 90 to 110 μm.

Moreover, in another embodiment of the present invention, the pad and the ground-removed portion comprise a rectangular outer shape.

Furthermore, in yet another embodiment of the present invention, the pad is formed in plurality, and a shortest distance between each of the pads is not less than 250 μm.

Furthermore, in yet another embodiment of the present invention, the pad and the ground-removed portion comprise circular or elliptical outer shapes.

Furthermore, in yet another embodiment of the present invention, the flexible printed circuit board comprises a microstrip line structure.

A flexible printed circuit board according to another embodiment of the present invention includes: a base substrate; a plurality of pads formed on one surface side of the base substrate; and a ground plane layer formed on the other surface side of the base substrate, the ground plane layer including a plurality of ground-removed portions, the ground-removed portions being formed at positions facing the pads via the base substrate so as to be of similar shapes to the pads and have outer shapes each extended 100±50 μm outwardly from outer shapes of the pads.

In one embodiment of the present invention, a shortest distance between the pads is not less than 250 μm.

Moreover, in another embodiment of the present invention, a shortest distance between the pads is set in range of 150 μm to 350 μm.

Furthermore, in yet another embodiment of the present invention, differences in outer shapes between the pads and the ground-removed portions are 90 to 110 μm.

Furthermore, in yet another embodiment of the present invention, the pads and the ground-removed portions comprise rectangular outer shapes.

Furthermore, in yet another embodiment of the present invention, the pads and the ground-removed portions comprise circular or elliptical outer shapes.

Furthermore, in yet another embodiment of the present invention, the flexible printed circuit board comprises a microstrip line structure.

The present invention results in a flexible printed circuit board that has outstanding high frequency characteristics and realizes a stable characteristic impedance while having good flexibility.

### BRIEF DESCRIPTION OF THE DRAWINGS

FIG. 1 is a plan view showing a structure of a flexible printed circuit board according to one embodiment of the present invention.

FIG. 2 is a cross-sectional view taken along the line A-A′ of FIG. 1.

FIG. 3 is a cross-sectional view showing lines of electric force in same flexible printed circuit board.

FIG. 4 is a diagram for explaining characteristic impedance measured by a TDR method in same flexible printed circuit board.

FIG. 5 is a diagram showing a relationship between characteristic impedance and offset amount of the ground-removed portion in the flexible printed circuit board in an example of the present invention.

FIG. 6 is a diagram showing a relationship between offset amount of the ground-removed portion and characteristic impedance in the flexible printed circuit board in same example.

FIG. 7 is a plan view showing a structure of a flexible printed circuit board according to other embodiment of the present invention.

FIG. 8 is a plan view showing a structure of a flexible printed circuit board according to other embodiment of the present invention.

FIG. 9 is a plan view showing a structure of a flexible printed circuit board according to other embodiment of the present invention.

FIG. 10 is a plan view showing a structure of a flexible printed circuit board according to other embodiment of the present invention.

### DETAILED DESCRIPTION OF THE EMBODIMENTS

Flexible printed circuit boards according to embodiments of this invention are described in detail below with reference to the accompanying drawings.

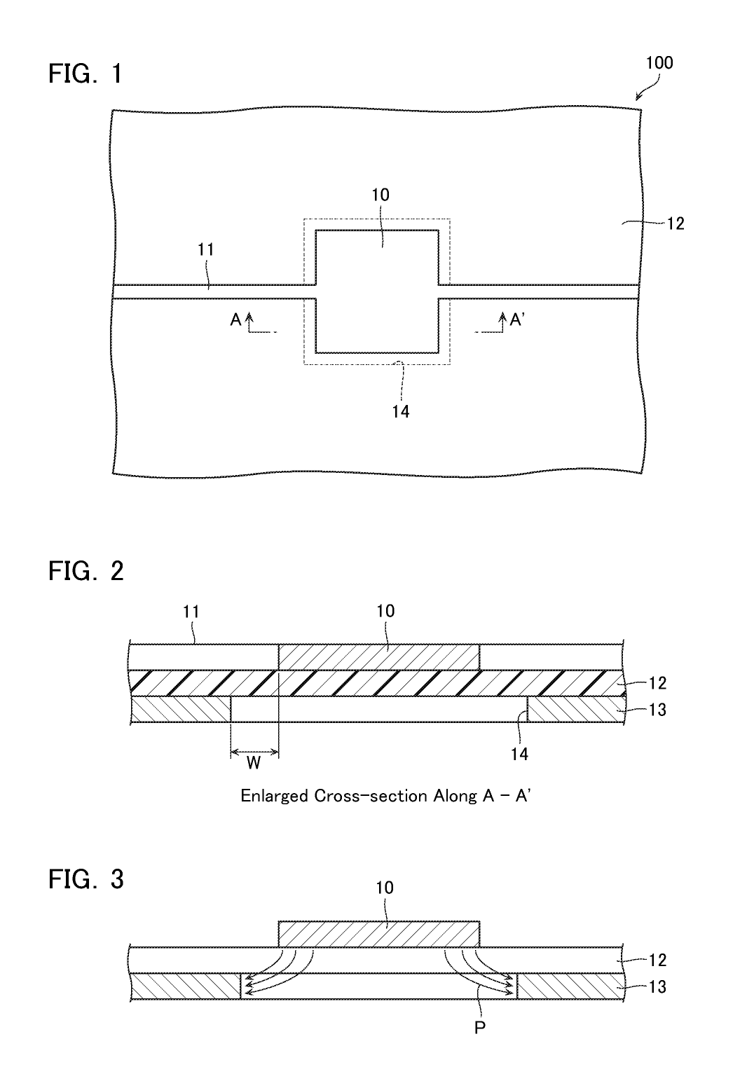

FIG. 1 is a plan view showing a structure of a flexible printed circuit board according to one embodiment of the present invention. FIG. 2 is a cross-sectional view taken along the line A-A′ of FIG. 1. FIG. 3 is a cross-sectional view showing lines of electric force in the flexible printed circuit board. A flexible printed circuit board 100 according to the present embodiment is employed in various kinds of circuits for signal transmission and comprises, for example, a microstrip line structure for high-speed signal transmission.

As shown in FIG. 1 and FIG. 2, the flexible printed circuit board 100 is formed basically as a three layer CCL (Copper Clad Laminate), and is configured comprising: a base substrate 12 configured from a polyimide resin (PI) having a thickness of 25, 50, or 75 μm, for example; an adhesive agent layer (not illustrated) formed on both surfaces of this base substrate 12 and configured from an epoxy adhesive agent having a thickness of 10 μm, for example; and a wiring 11 and a ground plane layer 13 attached via these adhesive agent layers and configured from copper foil having a thickness of 20 μm, for example. Note that a cover layer (not illustrated) is formed on the wiring 11.

The wiring 11 is a microstrip line having a width of about 150 μm, for example. Moreover, the ground plane layer 13 is formed on an entire lower surface of the base substrate 12. A pad 10 such as a component mounting pad or a connector pad is formed in a part of the wiring 11. The pad 10 has a rectangular shape, for example, and is formed having a broader width than the wiring 11. The cover layer is not formed on the pad 10.

This cover layer is configured comprising: a cover lay configured from an insulating material such as polyimide resin, for example; and an adhesive agent layer disposed on a lower surface of the cover lay and configured from an epoxy adhesive agent. A ground-removed portion 14 is formed at a position in the ground plane layer 13 facing the pad 10 via the base substrate 12, the ground-removed portion 14 being hollowed out so as to be of similar shape to the pad 10 and have an outer shape extended 100±50 μm outwardly from an outer shape of the pad 10. That is, an offset amount W between the pad 10 and the ground-removed portion 14 is 100±50 μm.

In the flexible printed circuit board 100 configured in this way, as shown in FIG. 3, lines of electric force P are concentrated between sides of the pad 10 and sides of the ground-removed portion 14. However, because the ground plane layer 13 does not exist on an underside of the pad 10, capacitance C is reduced and characteristic impedance Zo shown by Zo=✓(L/C) increases to become similar to those of a portion of the wiring 11. Moreover, because there is a three layer structure where the pad 10 and the ground plane layer 13 in which the ground-removed portion 14 is formed are formed on both surfaces of the base substrate 12, the flexible printed circuit board 100 can be configured extremely thinly. As a result, the flexible printed circuit board 100 has outstanding high frequency characteristics and realizes a stable characteristic impedance while having good flexibility.

### Example

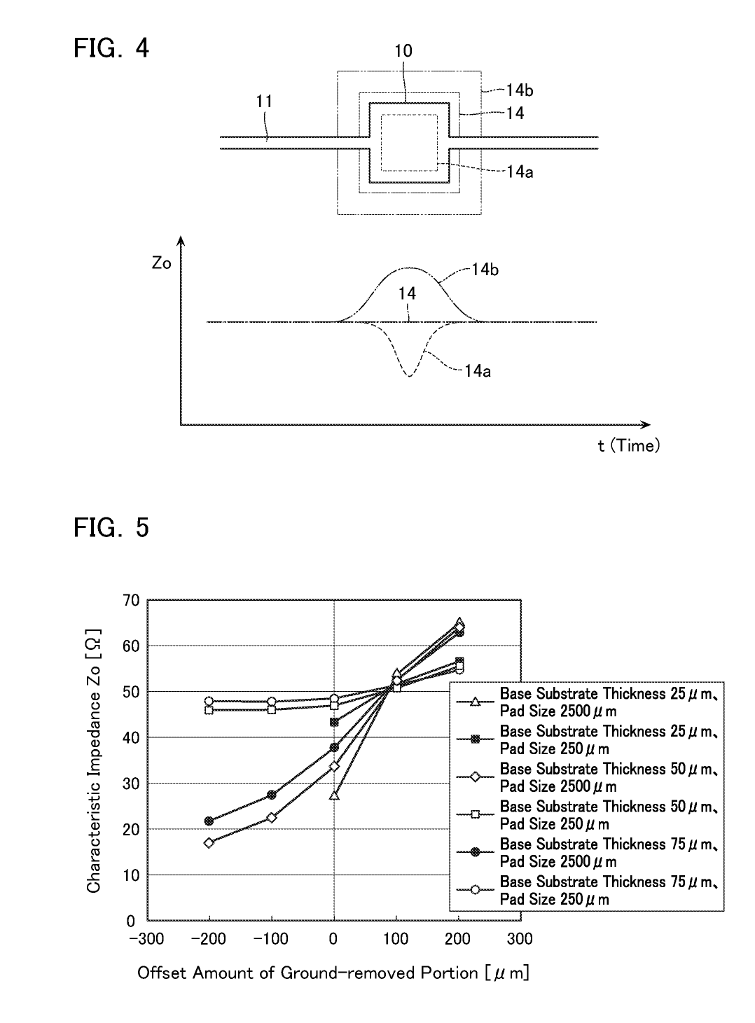

Next, specific electrical characteristics of the flexible printed circuit board 100 according to the present embodiment are described. FIG. 4 is a diagram for explaining characteristic impedance measured by a TDR (Time Domain Reflectometry) method in the flexible printed circuit board 100. As shown in FIG. 4, according to experiments conducted by the applicant of the present application, when the ground-removed portion 14 is formed larger than the pad 10 with an offset amount W of 100±50 μm to a plus side, characteristic impedance is constant and stable from a wiring 11 portion to a pad 10 portion as shown by the dashed-single dotted line.

On the other hand, in a ground-removed portion 14b where the offset amount W on the plus side is excessively larger than the pad 10, characteristic impedance of the pad 10 portion increases to be more than that of the wiring 11 portion as shown by the dashed-two dotted line. Moreover, in a ground-removed portion 14a offset to a minus side of the pad 10, characteristic impedance of the pad 10 portion is reduced over that of the wiring 11 portion as shown by the broken line.

In view of such results, the applicant of the present application produced the following sample circuit boards and measured characteristic impedance of these sample circuit boards by the TDR method. That is, the applicant produced sample circuit boards having pad size of the pad 10 changed to 250 μm and 2500 μm per side and having thickness of the base substrate 12 changed to 25 μm, 50 μm, and 75 μm, and measured characteristic impedance of each of the sample circuit boards while changing the offset amount W of the ground-removed portion 14 of each of the sample circuit boards.

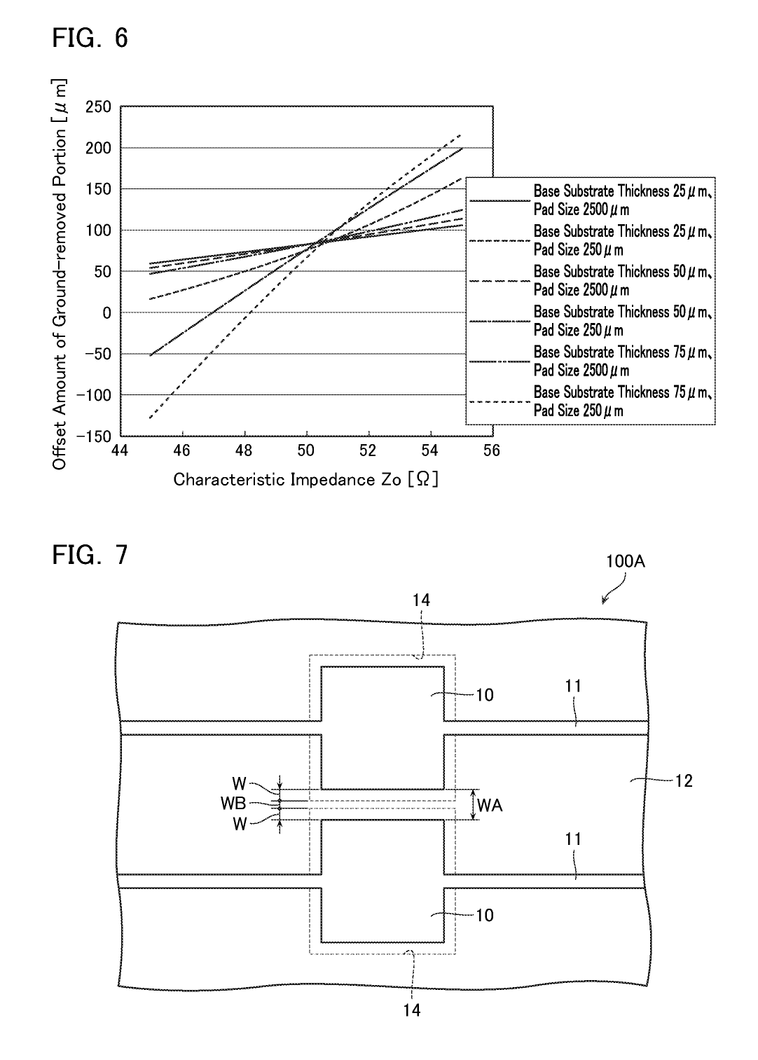

FIG. 5 is a diagram showing a relationship between characteristic impedance and offset amount of the ground-removed portion in the flexible printed circuit board in an example of the present invention. FIG. 6 is a diagram showing a relationship between offset amount of the ground-removed portion and characteristic impedance in the flexible printed circuit board in the example of the present invention.

As shown in FIG. 5, when the offset amount W of the ground-removed portion 14 is 90 μm to 110 μm, effects due to base substrate thickness and pad size are not received, and characteristic impedance Zo is substantially constant at 50 Ω2, which is substantially equivalent to a design value of characteristic impedance mainly employed for high-speed signal transmission. The content of FIG. 5 is summarized in the following Table 1.

TABLE 1

| | | Base Substrate Thickness [μm] | | | | | |
|---|---|---|---|---|---|---|---|
| | | 50 | 50 | 25 | 25 | 75 | 75 |
| | | Pad Size [μm] | | | | | |
| | | 2500 | 250 | 2500 | 250 | 2500 | 250 |
| | | Characteristic Impedance Zo [Ω] | | | | | |
| Offset Amount of | −200 | 16.68 | 45.9 | | | 21.44 | 47.53 |
| Ground-removed | −100 | 22.12 | 45.78 | | | 27.11 | 47.55 |
| Portion [μm] | 0 | 33.64 | 46.9 | 27.32 | 43.16 | 37.31 | 48.14 |
| | 100 | 52.59 | 50.87 | 53.56 | 51.56 | 52.09 | 50.99 |
| | 200 | 63.73 | 55.04 | 64.8 | 56.09 | 62.52 | 54.5 |

As a result, it was found that setting a shape of the ground-removed portion 14 in the ground plane layer 13 on the reverse side of the pad 10 to a shape offset about 100 μm to the plus side from the shape of the pad 10 enables reflection of signals at the pad 10 to be reduced.

Moreover, as shown in FIG. 6, checking the offset amount W of the ground-removed portion 14 when attaining characteristic impedance Zo according to differences in base substrate thickness and pad size in each of the sample circuit boards also leads to similar results. The content of this FIG. 6 is summarized in the following Table 2.

TABLE 2

| | Offset Amount of Ground-removed Portion [μm] | | | | | |
|---|---|---|---|---|---|---|
| | Base | Base | Base | Base | Base | Base |
| | Substrate | Substrate | Substrate | Substrate | Substrate | Substrate |
| | Thickness | Thickness | Thickness | Thickness | Thickness | Thickness |
| | 25 μm | 25 μm | 50 μm | 50 μm | 75 μm | 75 μm |
| | Pad Size | Pad Size | Pad Size | Pad Size | Pad Size | Pad Size |
| | 2500 μm | 250 μm | 2500 μm | 250 μm | 2500 μm | 250 μm |
| Zo = 45 Ω | 61 | 18 | 55 | −50 | 48 | −125 |
| Zo = 48 Ω | 73 | 52 | 72 | 28 | 69 | −6 |
| Zo = 49 Ω | 78 | 64 | 77 | 54 | 77 | 33 |
| Zo = 50 Ω | 82 | 77 | 83 | 79 | 84 | 68 |
| Zo = 51 Ω | 87 | 91 | 90 | 103 | 92 | 101 |
| Zo = 52 Ω | 92 | 106 | 96 | 128 | 99 | 132 |
| Zo = 53 Ω | 108 | 164 | 117 | 199 | 124 | 216 |

As mentioned above, characteristic impedance Zo is usually designed to 50 Ω2, moreover, a tolerance of ±10% (at maximum ±20%) from the design value is frequently set as a tolerance range. Accordingly, the offset amount W of the ground-removed portion 14 resulting in characteristic impedance Zo having a range of 50 Ω2 ±10% is examined. First, it is found that when base substrate thickness is 25 μm and pad size of the pad 10 is 2500 μm, a range of the offset amount W of the ground-removed portion 14 leading to characteristic impedance Zo being 50 Ω2 ±10% is narrow, and characteristic impedance Zo falls within the range of 50 Ω2 ±10% when the offset amount W of the ground-removed portion 14 is 61 μm to 108 μm.

Moreover, it is found that under such conditions, if base substrate thickness is greater than 25 μm or pad size is less than 2500 μm, characteristic impedance Zo falls within the range of 50 Ω2 ±10%.

Additionally, it is found that in the case that base substrate thickness is 50 μm and when pad size is 2500 μm, a range of the offset amount W of the ground-removed portion 14 leading to characteristic impedance Zo being 50 Ω2 ±10% is narrow, and characteristic impedance Zo falls within the range of 50 Ω2 ±10% when the offset amount W of the ground-removed portion 14 is 55 μtm to 117 μm.

Moreover, it is found that under such conditions, if base substrate thickness is greater than 50 μm or pad size is less than 2500 μm, characteristic impedance Zo falls within the range of 50 Ω2 ±10%.

Furthermore, it is found that in the case that base substrate thickness is 75 μm and when pad size is 2500 μm, a range of the offset amount W of the ground-removed portion 14 leading to characteristic impedance Zo being 50 106 2 ±10% is narrow, and characteristic impedance Zo falls within the range of 50 Ω2 ±10% when the offset amount W of the ground-removed portion 14 is 48 μm to 124 μm.

Moreover, it is found that under such conditions, if base substrate thickness is greater than 75 μm or pad size is less than 2500 μm, characteristic impedance Zo falls within the range of 50 Ω2 ±10%. Therefore, it was found that if the offset amount W is 100±50 μtm, and preferably 90 μm to 110 μm to a plus side, characteristic impedance Zo can be set to within the range of 50 Ω2 ±10%.

FIG. 7 is a plan view showing a structure of a flexible printed circuit board according to other embodiment of the present invention. A flexible printed circuit board 100A according to the present embodiment differs from the flexible printed circuit board 100 according to the previous embodiment in having a plurality of the pads 10 and ground-removed portions 14 disposed in parallel.

In this case, if the offset amount W is set to 100 μtm for each, a distance WA between the pads 10 is formed to be 250 μm or more. Therefore, a distance WB between the ground-removed portions 14 in this case is 50 μm. If the distance WB is fixed at 50 μm and the offset amount W set to the range of 100±50 μm, the distance WA is set in a range of 150 μm to 350 μm. Operational advantages of the kind mentioned above can be displayed, even when such a configuration is adopted.

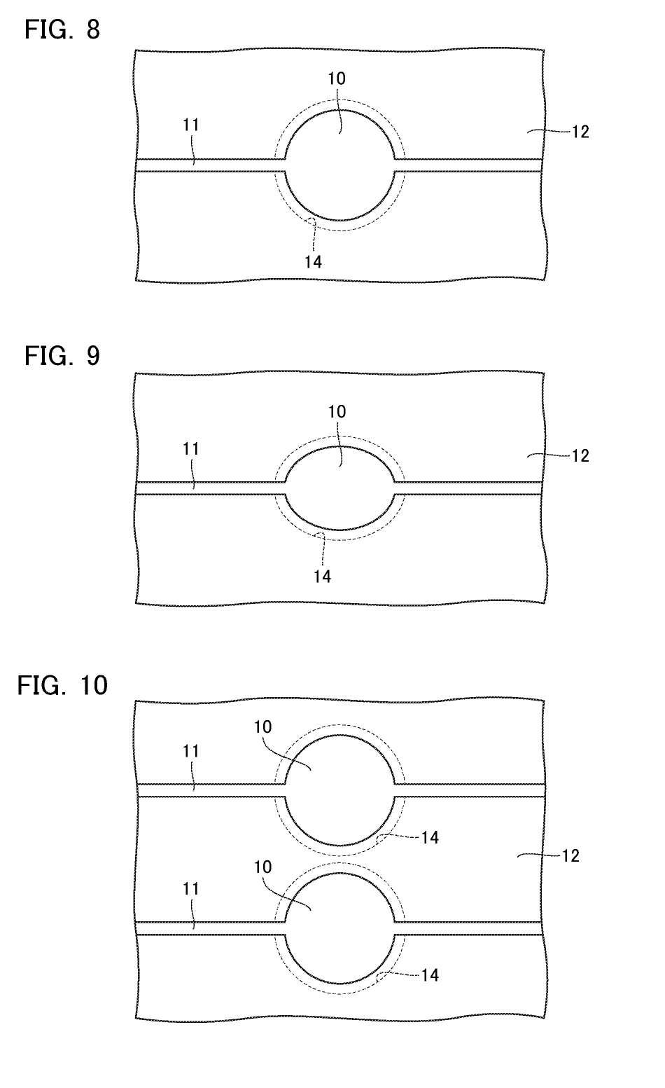

Note that the above-mentioned embodiments were described assuming the flexible printed circuit boards 100 and 100A to have a microstrip line structure for high-speed signal transmission. However, the flexible printed circuit boards according to the present invention are not limited to having this structure, and the present invention may be applied to various kinds of circuits for electrical signal transmission, and so on. For example, as shown in FIGS. 8-10, the pad 10 and the ground-removed portions 14 can be formed a circular or elliptical outer shape.

What is claimed is:

1. A flexible printed circuit board including:
a base substrate;
a pad formed on one surface side of the base substrate; and
a ground plane layer formed on the other surface side of the base substrate, the ground plane layer including a ground-removed portion, the ground-removed portion being formed at a position facing the pad via the base substrate so as to be of similar shape to the pad and have an outer shape extended 100±50 μm outwardly from an outer shape of the pad.

2. The flexible printed circuit board according to claim 1, wherein
a difference in outer shape between the pad and the ground-removed portion is 90 to 110 μm.

3. The flexible printed circuit board according to claim 1, wherein
the pad and the ground-removed portion comprise rectangular outer shapes.

4. The flexible printed circuit board according to claim 1, wherein
the pad and the ground-removed portion comprise circular or elliptical outer shapes.

5. The flexible printed circuit board according to claim 1, wherein
the flexible printed circuit board comprises a microstrip line structure.

6. A flexible printed circuit board including:
a base substrate;
a plurality of pads formed on one surface side of the base substrate; and
a ground plane layer formed on the other surface side of the base substrate, the ground plane layer including a plurality of ground-removed portions, the ground-removed portions being formed at positions facing the pads via the base substrate so as to be of similar shapes to the pads and have outer shapes each extended 100±50 μm outwardly from outer shapes of the pads.

7. The flexible printed circuit board according to claim 6, wherein
a shortest distance between the pads is not less than 250 μm.

8. The flexible printed circuit board according to claim 6, wherein
a shortest distance between the pads is set in range of 150 μm to 350 μm.

9. The flexible printed circuit board according to claim 6, wherein
differences in outer shapes between the pads and the ground-removed portions are 90 to 110 μm.

10. The flexible printed circuit board according to claim 6, wherein
the pads and the ground-removed portions comprise rectangular outer shapes.

11. The flexible printed circuit board according to claim 6, wherein
the pads and the ground-removed portions comprise circular or elliptical outer shapes.

12. The flexible printed circuit board according to claim 6, wherein
the flexible printed circuit board comprises a microstrip line structure.
